(19) United States
(12) Patent Application Publication
(10) Pub. No.: US 2026/0343731 A1
(43) Pub. Date: Oct. 29, 2026

(54) WIRING SUBSTRATE AND METHOD FOR MANUFACTURING WIRING SUBSTRATE

(71) Applicant: IBIDEN CO., LTD., Gifu (JP)

(72) Inventors: Yuma ITO, Gifu (JP); Kyohei YOSHIKAWA, Gifu (JP); Jun SAKAI, Gifu (JP); Atsushi HARA, Gifu (JP)

(73) Assignee: IBIDEN CO., LTD., Gifu (JP)

(21) Appl. No.: 19/534,232

(22) Filed: Feb. 9, 2026

(30) Foreign Application Priority Data
Feb. 10, 2025 (JP) 2025-020311

(51) Int. Cl. H05K 1/02; H05K 3/02

(52) U.S. Cl. CPC H05K 1/0296; H05K 3/027

(57) ABSTRACT

A wiring substrate includes a first insulating layer, a conductive layer formed on the first insulating layer and including wirings, and a second insulating layer formed on the first insulating layer such that the second insulating layer is covering the conductive layer. The conductive layer is formed such that the wirings have the minimum wiring width of 3 μm or less and the minimum inter-wiring distance of 3 μm or less and has side surfaces having concave and convex portions forming vertical stripes extending along the thickness direction of the conductor layer.

### CROSS-REFERENCE TO RELATED APPLICATIONS

The present application is based upon and claims the benefit of priority to Japanese Patent Application No. 2025-020311, filed Feb. 10, 2025, the entire contents of which are incorporated herein by reference.

### BACKGROUND OF THE INVENTION

### Field of the Invention

The present invention relates to a wiring substrate and a method for manufacturing a wiring substrate.

### Description of Background Art

Japanese Patent Application Laid-Open Publication No. 2000-252622 describes a printed wiring substrate. The entire contents of this publication are incorporated herein by reference.

### SUMMARY OF THE INVENTION

According to one aspect of the present invention, a wiring substrate includes a first insulating layer, a conductive layer formed on the first insulating layer and including wirings, and a second insulating layer formed on the first insulating layer such that the second insulating layer is covering the conductive layer. The conductive layer is formed such that the wirings have the minimum wiring width of 3 μm or less and the minimum inter-wiring distance of 3 μm or less and has side surfaces having concave and convex portions forming vertical stripes extending along the thickness direction of the conductor layer.

According to another aspect of the present invention, a method for manufacturing a wiring substrate includes forming a conductor layer on a first insulating layer, and forming a second insulating layer on the first insulating layer such that the second insulating layer covers the conductor layer. The forming the conductor layer includes forming a metal film layer on the first insulating layer, forming a plating film layer having patterns on the metal film layer, and applying ion beam etching on the metal film and plating film layers such that portions of the metal film layer exposed from the patterns of the plating film layer are removed and that concave and convex portions forming vertical stripes and extending along a thickness direction of the conductor layer are formed on side surfaces of the conductor layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating an example of a wiring substrate according to an embodiment of the present invention;

FIG. 2 is an enlarged view of a region (II) in FIG. 1;

FIG. 3 is a perspective view for describing a conductor layer in a wiring substrate according to an embodiment of the present invention;

FIG. 4 is a side view for describing a conductor layer in a wiring substrate according to an embodiment of the present invention;

FIG. 5A is a cross-sectional view illustrating an example of a method for manufacturing a wiring substrate according to an embodiment of the present invention;

FIG. 5B is a cross-sectional view illustrating an example of a method for manufacturing a wiring substrate according to an embodiment of the present invention;

FIG. 5C is a cross-sectional view illustrating an example of a method for manufacturing a wiring substrate according to an embodiment of the present invention;

FIG. 5D is a cross-sectional view illustrating an example of a method for manufacturing a wiring substrate according to an embodiment of the present invention;

FIG. 5E is a cross-sectional view illustrating an example of a method for manufacturing a wiring substrate according to an embodiment of the present invention;

FIG. 5F is a cross-sectional view illustrating an example of a method for manufacturing a wiring substrate according to an embodiment of the present invention;

FIG. 5G is a cross-sectional view illustrating an example of a method for manufacturing a wiring substrate according to an embodiment of the present invention;

FIG. 5H is a cross-sectional view illustrating an example of a method for manufacturing a wiring substrate according to an embodiment of the present invention;

FIG. 5I is a cross-sectional view illustrating an example of a method for manufacturing a wiring substrate according to an embodiment of the present invention;

FIG. 5J is a cross-sectional view illustrating an example of a method for manufacturing a wiring substrate according to an embodiment of the present invention;

FIG. 5K is a cross-sectional view illustrating an example of a method for manufacturing a wiring substrate according to an embodiment of the present invention;

FIG. 5L is a cross-sectional view illustrating an example of a method for manufacturing a wiring substrate according to an embodiment of the present invention; and

FIG. 5M is a cross-sectional view illustrating an example of a method for manufacturing a wiring substrate according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

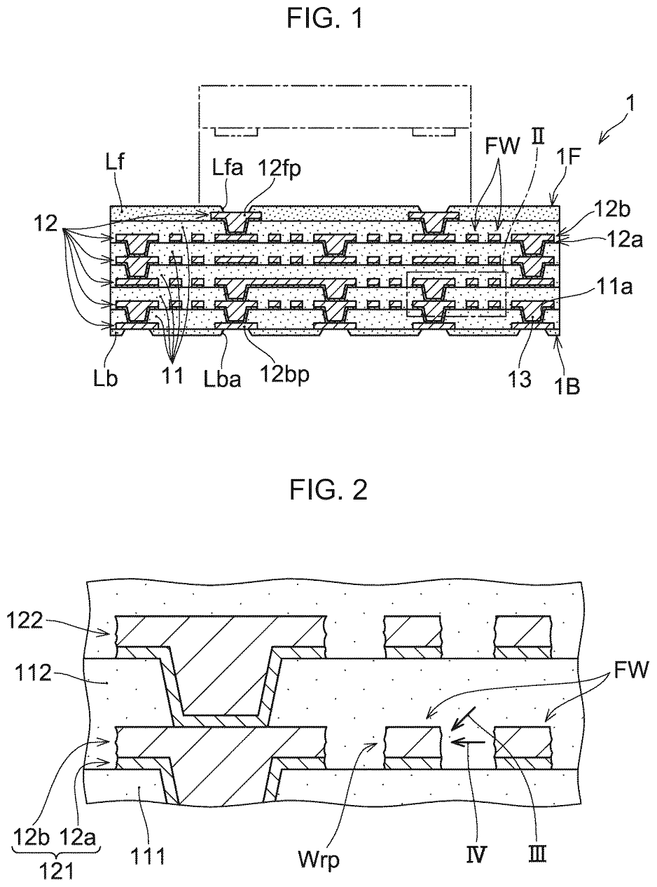

FIG. 1 is a cross-sectional view illustrating a wiring substrate 1, which is an example of a wiring substrate according to an embodiment of the present invention. A laminated structure of the wiring substrate of the embodiment, and the number of conductor layers and insulating layers, are not limited to the laminated structure of the wiring substrate 1 of FIG. 1 and the number of the conductor layers and insulating layers in the wiring substrate 1.

The wiring substrate 1 has two surfaces (a first surface (1F) and a second surface (1B) on an opposite side with respect to the first surface (1F)) orthogonal to its thickness direction. The wiring substrate 1 includes insulating layers 11 and conductor layers 12 that are alternately laminated. Conductor layers 12 facing each other with one insulating layer 11 interposed therebetween are connected by via conductors 13. In the illustrated example, the conductor layer 12 constituting a part of the first surface (1F) is formed to have patterns including multiple conductor pads (12fp). The conductor layer 12 constituting a part of the second surface (1B) is formed to have patterns including multiple conductor pads (12bp).

In the description of the wiring substrate 1 illustrated in FIG. 1, the first surface (1F) side of the wiring substrate 1 is also referred to as “upper” or an “upper side,” and the second surface (1B) side of the wiring substrate 1 is also referred to as “lower” or a “lower side.” Further, for each of the structural elements, a surface facing the first surface (1F) side of the wiring substrate 1 is also referred to as an “upper surface,” and a surface facing the second surface (1B) side of the wiring substrate 1 is also referred to as a “lower surface.”

The insulating layers 11 can be formed, for example, using an insulating resin such as epoxy resin or phenol resin. The insulating layers 11 may contain any one of fluorine resin, liquid crystal polymer (LCP), fluorinated ethylene resin (PTFE), polyester resin (PE), and modified polyimide resin (MPI).

Examples of a conductor constituting the conductor layers 12 and the via conductors 13 include copper, nickel, and the like, and copper is preferably used. Each of the conductor layers 12 and via conductors 13 have a multilayer structure. The conductor layers 12 and the via conductors 13 each have a two-layer structure including a metal film layer (12a), which is preferably a copper sputtering film layer or an electroless copper plating film layer, and a plating film layer (12b), which is preferably an electrolytic copper plating film layer.

The via conductors 13 that penetrate the insulating layers 11 in the thickness direction are formed by filling through holes (11a) penetrating the insulating layers 11 with a conductive material. In the example illustrated in FIG. 1, each via conductor 13 is integrally formed with a conductor layer 12 provided on the upper side thereof. Therefore, the via conductor 13 and the conductor layer 12 can be formed by the same metal film layer and plating film layer.

In the example illustrated in FIG. 1, the wiring substrate 1 includes a solder resist layer (Lf) formed on the uppermost insulating layer 11 and conductor layer 12, as well as a solder resist layer (Lb) formed under the lowermost insulating layer 11 and conductor layer 12. The solder resist layers (Lf, Lb) are formed, for example, using a photosensitive polyimide resin or epoxy resin. Openings (Lfa) are formed in the solder resist layer (Lf), and the conductor pads (12fp) are exposed from the openings (Lfa). Openings (Lba) are formed in the solder resist layer (Lb), and the conductor pads (12bp) are exposed from the openings (Lba). That is, the first surface (1F) of the wiring substrate 1 includes a surface of the solder resist layer (Lf) and surfaces of the conductor pads (12fp), and the second surface (1B) of the wiring substrate 1 includes a surface of the solder resist layer (Lb) and surfaces of the conductor pad (12bp).

The first surface (1F) of the wiring substrate 1 constitutes a component mounting surface to which external electronic components can be connected. The second surface (1B) on an opposite side with respect to the component mounting surface of the wiring substrate 1 can be a connection surface that is to be connected to an external element such as an external wiring substrate (for example, a motherboard of any electrical device) when the wiring substrate 1 itself is mounted on the external element.

The conductor layers 12 included in the wiring substrate 1 are each patterned to have predetermined conductor patterns. The conductor layers 12 include relatively fine wirings and shave relatively high-density circuit wirings. Specifically, the conductor layers 12 of the wiring substrate 1 have wirings (FW), which are high-density wirings with relatively small wiring widths and inter-wiring distances (wiring intervals). The wirings (FW) have a minimum wiring width of 3 μm or less, and a minimum inter-wiring distance of 3 μm or less. In the illustrated example, among the multiple conductor layers 12 included in the wiring substrate 1, four conductor layers 12 are provided with the wirings (FW), which are high-density wirings. In the wiring substrate 1, any number of conductor layers 12 may be provided with the wirings (FW). The number of conductor layers 12 in the wiring substrate 1 that include the wirings (FW) is not limited.

When the conductor layers 12 are formed to include the wirings (FW) as described above, it may be preferable that the via conductors 13 connecting conductor layers 12 facing each other across an insulating layer 11 are also formed at a fine pitch. Through holes (11a) for via conductors 13 having small diameters can be formed in the insulating layers 11. Therefore, although the insulating layers 11 can contain inorganic fillers such as fine particles made of silica (SiO2), alumina, mullite, or the like, in order to facilitate the formation of the through holes (11a) having small diameters, it may be preferable that the insulating layers 11 do not contain inorganic fillers. Further, it is also preferable that insulating layers 11 do not contain a core material (reinforcing material) made of glass fibers, aramid fibers, or the like. In the wiring substrate 1, the insulating layers 11 each have a thickness of, for example, 0.4 μm or more and 15 μm or less, and more preferably 2 μm or more and 10 μm or less. The conductor layers 12 each have a thickness of 0.2 μm or more and 10 μm or less, and more preferably 1 μm or more and 5 μm or less. The metal film layer (12a), which cany be a sputtering film layer formed by sputtering, has a thickness of, for example, 0.02 μm or more and 0.5 μm or less, and more preferably 0.1 μm or more and 0.2 μm or less. The plating film layer (12 b), which can be an electrolytic plating film layer formed by electrolytic plating, has a thickness that can be determined according to the thickness of the conductor layers 12 and the thickness of the metal film layer (12a). When the metal film layer (12a) is formed by sputtering, the sputtering film layer can include two or more sputtered films made of mutually different metal materials. For example, the metal film layer (12a) can be formed of multiple layers including a sputtered titanium film and a sputtered copper film. For example, a metal film layer (12a) having a thickness of 0.15 μm can be formed, consisting of two layers: a sputtered titanium film having a thickness of 0.05 μm and a sputtered copper film having a thickness of 0.1 μm.

Next, with reference to FIGS. 2 to 4, a structure of the conductor layers 12 included in the wiring substrate 1 is described in detail. In the description with reference to FIGS. 2 to 4, for simplicity of description, the lowermost insulating layer among the insulating layers illustrated in FIG. 2 is referred to as a first insulating layer 111, and the conductor layer formed in contact with an upper surface of the first insulating layer 111 is referred to as a first conductor layer 121. Further, the insulating layer formed on the first conductor layer 121 and on the first insulating layer 111 exposed from the conductor patterns of the first conductor layer 121 is referred to as a second insulating layer 112, and the conductor layer formed in contact with an upper surface of the second insulating layer 112 is referred to as a second conductor layer 122.

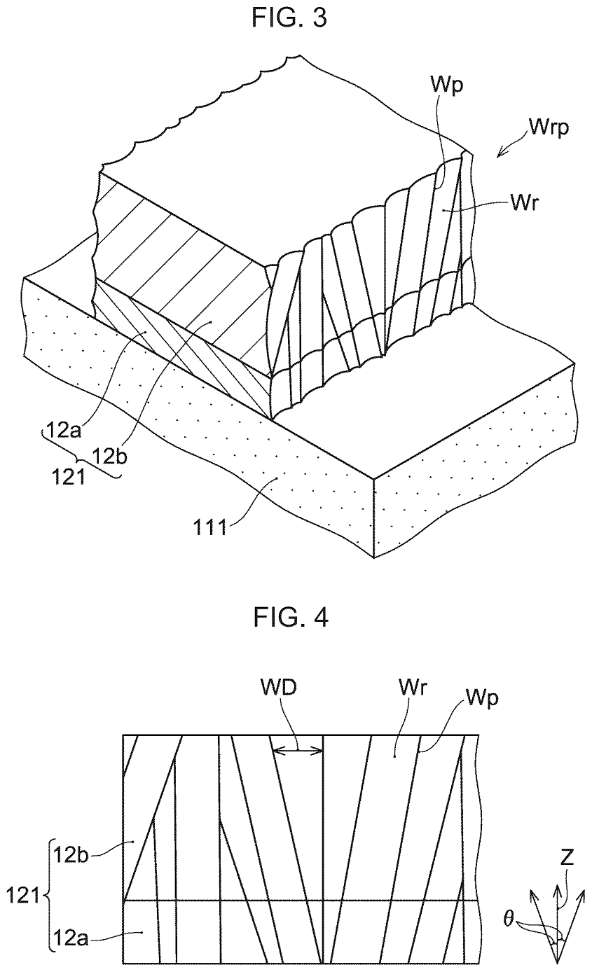

FIG. 2 illustrates an enlarged view of a region (II) surrounded by a one-dot chain line in FIG. 1. As will be described in detail later with reference to FIGS. 3 and 4, concave and convex portions (Wrp) is formed on side surfaces of the conductor patterns of the first conductor layer 121, which includes the wirings (FW). As will be described in detail later in a method for manufacturing the wiring substrate, the concave and convex portions (Wrp) is formed in a process of removing the metal film layer (12a) exposed from patterns of the plating film layer (12b) during the formation of the first conductor layer 121.

The concave and convex portions (Wrp) formed on the side surfaces of the first conductor layer 121 are described in detail with reference to FIGS. 3 and 4. FIG. 3 illustrates a perspective view of the first conductor layer 121 when the first conductor layer 121 is viewed along an arrow (III) in FIG. 2. FIG. 4 illustrates a side surface of the first conductor layer 121 when the first conductor layer 121 is viewed along an arrow (IV), which is perpendicular to the side surface of the first conductor layer 121 in FIG. 2. In FIGS. 3 and 4, the second insulating layer 112 that covers the first conductor layer 121 is omitted.

As illustrated in FIGS. 3 and 4, the concave and convex portions (Wrp) formed on the side surfaces of the first conductor layer 121 has a striping pattern. The concave and convex portions (Wrp) is formed as striping concave and convex portions including multiple recesses (Wr) and protrusions (Wp) that constitute boundaries between adjacent recesses (Wr). Specifically, the concave and convex portions (Wrp) include multiple recesses (Wr) and protrusions (Wp) extending along the thickness direction of the first conductor layer 121.

In the description of the concave and convex portions (Wrp), the thickness direction of the first conductor layer 121 is also referred to as a vertical direction, and the striping concave and convex portions (Wrp) along the vertical direction is also referred to as “vertically striping concave and convex portions (Wrp).” The concave and convex portions (Wrp) extending “along the vertical direction” means that 90% or more of the multiple recesses (Wr) and protrusions (Wp) extend along a direction where deviation (θ) with respect to the thickness direction (Z) of the first conductor layer 121 is within 20 degrees. Since the vertically striping concave and convex portions (Wrp) is formed on the side surfaces of the first conductor layer 121, it is thought that the second insulating layer 112 (see FIG. 2) covering the first conductor layer 121 relatively firmly adheres to the side surfaces of the first conductor layer 121. As illustrated, the vertically striping concave and convex portions (Wrp) are formed over the entire side surfaces of the first conductor layer 121 (that is, the entire side surfaces of the first conductor layer 121 composed of the metal film layer (12a) and the plating film layer (12b)). The concave and convex portions (Wrp) are not formed on the upper surface of the first conductor layer 121.

As illustrated in FIG. 4, widths (WD) of the multiple recesses (Wr) in the vertically striping concave and convex portions (Wrp) (distances between adjacent protrusions (Wp) in a direction orthogonal to the vertical direction) are different. It is preferable that the maximum value of the widths (WD) of the recesses (Wr) in the vertically striping concave and convex portions (Wrp) (the distances between adjacent boundaries (protrusions (Wp))) is 0.2 μm or more and 1.0 μm or less. The number of protrusions (Wp) per unit length in a direction orthogonal to the vertical direction on the side surfaces of the first conductor layer 121 can be ensured to be equal to or greater than a desired number.

Therefore, it is thought that stronger adhesion between the first conductor layer 121 and the second insulating layer 112 (see FIG. 2) can be achieved.

In the wiring substrate of the embodiment, among the conductor layers 12 that constitute the wiring substrate, it is sufficient that any of the conductor layers that include the wirings (FW) have the vertically striping concave and convex portions (Wrp). Further, the vertically striping concave and convex portions (Wrp) may be formed on the side surfaces of all the conductor layers 12 included in the wiring substrate 1.

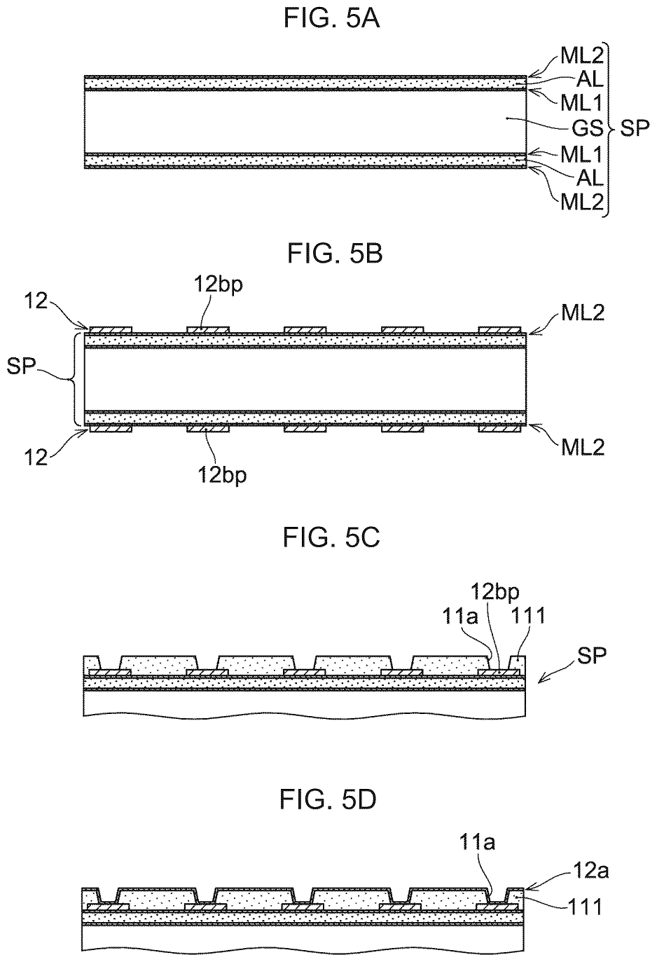

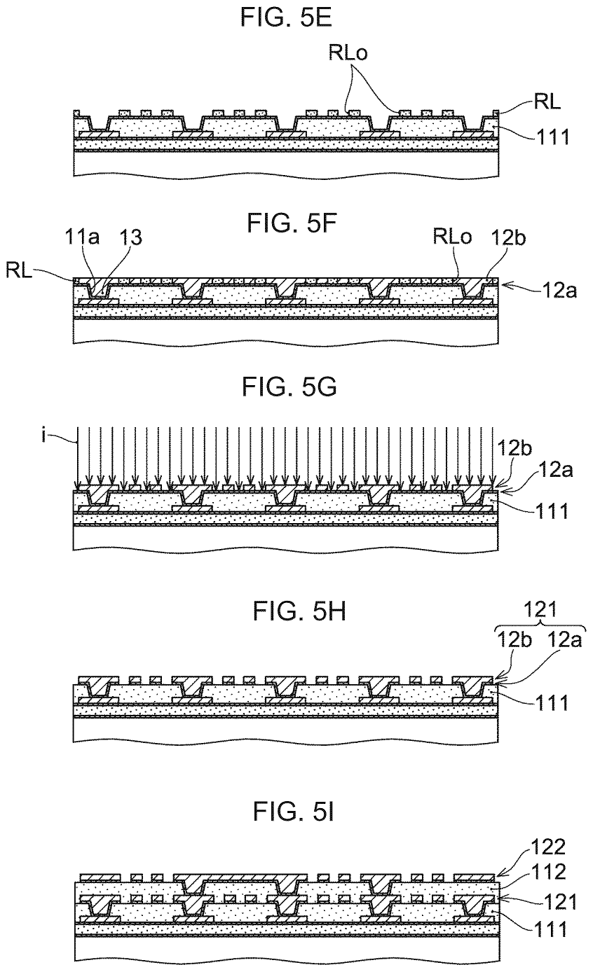

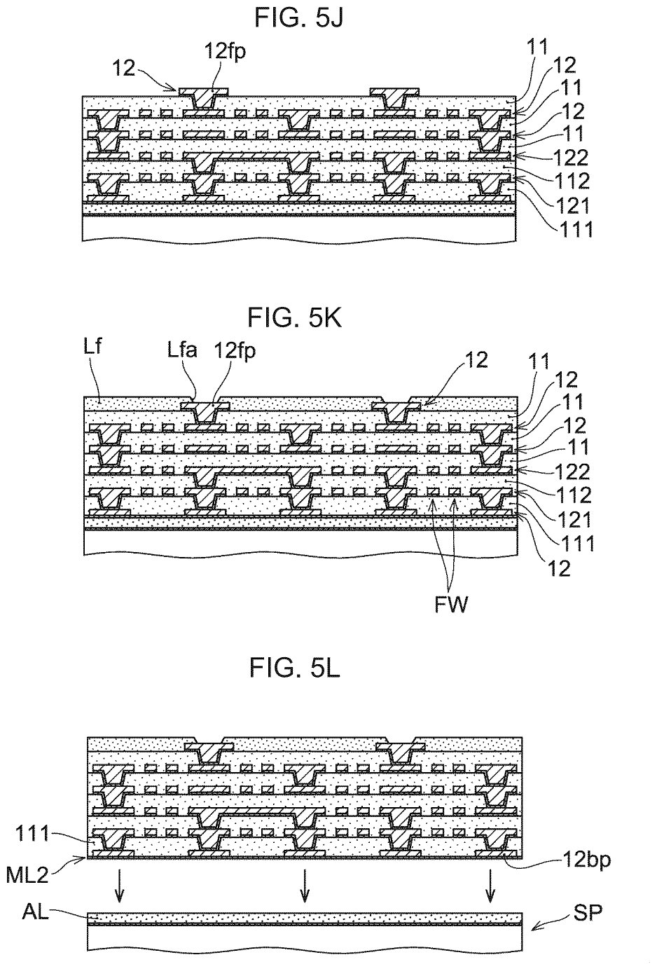

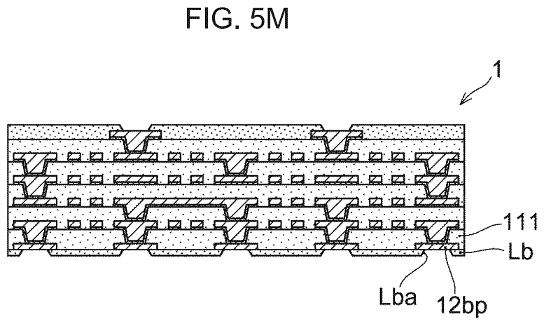

Next, with reference to FIGS. 5A to 5M, a method for manufacturing the wiring substrate of the embodiment is described, using a case where the wiring substrate 1 illustrated in FIG. 1 is manufactured as an example. Structural elements formed in the manufacturing method to be described below can be formed using the materials exemplified as the materials of the corresponding structural elements in the description of the wiring substrate 1 in FIG. 1, unless otherwise specified. In the following description about the method for manufacturing the wiring structure 1, a side closer to a core material (GS) constituting a support substrate (SP) is referred to as “lower” or a “lower side,” and a side farther from the support substrate (SP) is referred to as “upper” or an “upper side.” Therefore, of each of the elements constituting the wiring structure, a surface facing the support substrate (SP) is also referred to as a “lower surface,” and a surface facing away from the support substrate (SP) is also referred to as an “upper surface.” Further, in the description of the manufacturing method, similar to the description of the wiring substrate with reference to FIGS. 2 to 4, for simplicity, the insulating layer closest to the support substrate (SP) is referred to as the first insulating layer 111, the conductor layer formed in contact with the first insulating layer 111 is referred to as the first conductor layer 121, the insulating layer formed on the first conductor layer 121 is referred to as the second insulating layer 112, and the conductor layer formed in contact with the second insulating layer 112 is referred to as the second conductor layer 122.

First, as illustrated in FIG. 5A, the support substrate (SP) is prepared. In the method for manufacturing the wiring substrate of the embodiment, the support substrate (SP) to be used has good flatness on its two surfaces orthogonal to its thickness direction. The support substrate (SP) includes, for example, the core material (GS), which is a glass substrate, a first metal film layer (ML1) laminated on surfaces on both sides of the core material (GS), and a second metal film layer (ML2) laminated on the first metal film layer (ML1) via an adhesive layer (AL). The first and second metal film layers (ML1, ML2) are, for example, metal film layers formed by electroless plating or sputtering. In the illustration, the first and second metal film layers (ML1, ML2) are each depicted as a single layer, but they can each include multiple layers. For example, the first and second metal film layers (ML1, ML2) can each have a two-layer structure including a titanium layer and a copper layer. The adhesive layer (AL) can contain, for example, an azobenzene-based polymer adhesive that can be attached or detached by irradiation with light. The support substrate (SP) can include, as the core material (GS), a silicon substrate, a metal substrate, or a ceramic substrate, instead of a glass substrate.

Next, as illustrated in FIG. 5B, a conductor layer 12 having multiple conductor pads (12bp) is formed on the support substrate (SP). In forming the conductor layer 12 in contact with the support substrate (SP), for example, a plating resist is formed on the second metal film layer (ML2), and openings corresponding to pattern formation regions of the conductor pads (12bp) are formed in the plating resist, for example, using a photolithography technology. Next, a plating film layer is formed in the openings by electrolytic plating using the second metal film layer (ML2) as a seed layer. After the formation of the plating film layer, the plating resist is removed, and a state illustrated in FIG. 5B is formed.

Next, as illustrated in FIG. 5C, the first insulating layer 111 is laminated to cover the upper and side surfaces of the conductor layer 12, as well as the surface of the support substrate (SP) exposed from the conductor patterns of the conductor layer 12. As the first insulating layer 111, for example, an insulating resin such as epoxy resin or phenol resin can be used. The first insulating layer 111 is formed by thermocompression bonding these resins molded into a film-like shape. Next, through holes (11a) are formed at formation positions of the via conductors 13 (see FIG. 1) in the first insulating layer 111, for example, by irradiation with CO₂ laser light or excimer laser light.

Although not illustrated, the formation of the through holes (11a) by irradiation with laser such as CO₂ laser light can be performed by irradiating the laser while protecting the upper surface of the first insulating layer 111 by covering the upper surface with a protective film such as a polyethylene terephthalate (PET) filmor a polyethylene naphthalate (PEN) film. The through holes (11a) penetrating the protective film and the first insulating layer 111 are formed. Further, after the formation of the through holes (11a), a desmear treatment may be performed to prevent a decrease in adhesion or an increase in a resistance component or the like of the via conductors 13 due to a processing-deformed substance occurring at bottoms of the through holes (11a). The desmear treatment can preferably be a dry desmear treatment using a plasma gas. The desmear treatment may also be performed while protecting the surface of the first insulating layer 11 with the protective film formed on the surface of the first insulating layer 111.

In FIG. 5C, as well as FIGS. 5D-5M to be referenced below, the laminate formed on the surface on one side of the support substrate (SP) is illustrated, and illustration of the laminate that can be formed on the surface on the opposite side is omitted. However, on the surface on the opposite side of the support substrate (SP), a laminate with a similar structure and number of layers, or conductor layers and insulating layers with structures and number of layers different from those on the surface on the one side, may be formed, or it is also possible that such conductor layers and insulating layers are not formed.

Next, as illustrated in FIG. 5D, the metal film layer (12a) is formed on inner walls of the through holes (11a) and on the surface of the first insulating layer 111 by electroless plating, sputtering, or the like. Preferably, the metal film layer (12a) can be a sputtering film formed by sputtering. When the metal film layer (12a) is formed as a sputtering film layer, the metal film layer (12a) can be formed so as to include two or more sputtered films made of mutually different metal materials. As the metal film layer (12a), for example, a sputtering film layer having a two-layer structure including a sputtered titanium film and a sputtered copper film can be formed. When a protective film is provided on the surface of the first insulating layer 111 during the formation of the through holes (11a) and/or during the desmear treatment, the protective film can be peeled off and removed before formation of the metal film layer (12a).

Next, a dry film resist containing, for example, a photosensitive epoxy resin is adhered onto the metal film layer (12a), and a resist layer (RL) is formed. Subsequently, exposure and development of the resist layer (RL) are performed, and as illustrated in FIG. 5E, resist patterns corresponding to the conductor patterns of the first conductor layer 121 (see FIG. 1) to be formed on the first insulating layer 111 are formed in the resist layer (RL). Openings (RLo) corresponding to the wirings (FW) to be formed on the first insulating layer 111 are formed to have a minimum opening width of 3 μm or less and a minimum inter-opening distance of 3 μm or less.

Next, as illustrated in FIG. 5F, the plating film layer (12b) is formed in the openings (RLo) of the resist layer (RL) by electrolytic plating using the metal film layer (12a) as a power feeding layer. The through holes (11a) are completely filled with the plating film layer (12b), and the via conductors 13 are formed. A plating film layer (12b) having the conductor patterns of the first conductor layer 121 to be formed on the first insulating layer 111 is formed.

Next, the resist layer (RL) is removed using a stripping solution, and as illustrated in FIG. 5G, the upper surface of the metal film layer (12a) and the side surfaces of the plating film layer (12b) are exposed.

Subsequently, a portion of the metal film layer (12a) that is exposed by the removal of the resist layer (RL) and is not covered by the plating film layer (12b) is removed by etching. The etching is performed by ion beam etching. Ion beam etching is a processing method in which a source gas is plasma-ionized in a vacuum, and the resulting ions (i) are caused to collide with an object to be processed (here, the upper surface of the metal film layer (12a) and the upper surface of the plating film layer (12b)). As the source gas used for the ion beam etching, for example, argon is used. In this case, the ions (i) are monovalent argon ions.

In the ion beam etching, the ions (i) collide with the exposed upper surfaces of the metal film layer (12a) and the plating film layer (12b). The ions (i) also come into contact with the side surfaces of the plating film layer (12b), grazing the plating film layer (12b) along the thickness direction (vertical direction) of the plating film layer (12b). As a result, as illustrated in FIG. 5H, the metal film layer (12a) exposed from the patterns of the plating film layer (12b) is removed, and the upper surface of the first insulating layer 111 is exposed. On the side surfaces of the plating film layer (12b), the vertically striping concave and convex portions (Wrp) described above with reference to FIGS. 3 and 4 are formed. By the removal of the metal film layer (12a) by the ion beam etching, the side surfaces of the metal film layer (12a) on which the vertically striping concave and convex portions (Wrp) have been formed are exposed. The first conductor layer 121 having the vertically striping concave and convex portions (Wrp) on its side surfaces is formed.

As described above with reference to FIGS. 3 and 4, the vertically striping concave and convex portions (Wrp) formed on the side surfaces of the first conductor layer 121 can be formed such that the maximum value of the widths (WD) of the recesses (Wr) is 0.2 μm or more and 1.0 μm or less. In the ion beam etching, the ion beam forms plasma, and an acceleration voltage is applied to extract ions and impart directivity to the ions, thereby achieving a desired energy distribution, and the widths (WD) of the recesses (Wr) in the vertically striping concave and convex portions (Wrp) to be formed can be adjusted by controlling the acceleration voltage.

Next, as illustrated in FIG. 5I, the second insulating layer 112 is formed on the first conductor layer 121 and on the first insulating layer 111 exposed from the conductor patterns of the first conductor layer 121, and further, the second conductor layer 122 is formed on the second insulating layer 112, using methods similar to those used for forming the first insulating layer 111 and the first conductor layer 121. In forming the second insulating layer 112, an uncured second insulating layer 112 enters into spaces between the patterns of the first conductor layer 121. The uncured second insulating layer 112 is guided in the thickness direction (vertical direction) of the first conductor layer 121 by the vertically striping concave and convex portions (Wrp) formed on the side surfaces of the first conductor layer 121, and can enter into the spaces between the patterns of the first conductor layer 121 with relatively low resistance. Therefore, the second insulating layer 112 can smoothly enter even between patterns having a relatively narrow minimum wiring interval of 3 μm or less, and good adhesion between the first insulating layer 111 and the second insulating layer 112 can be achieved. Further, since the vertically striping concave and convex portions (Wrp) are formed on the side surfaces of the first conductor layer 121, a larger contact area between the second insulating layer 112 and the first conductor layer 121 is obtained, and good adhesion between the second insulating layer 112 and the first conductor layer 121 can be ensured.

Next, as illustrated in FIG. 5J, using methods similar to those described above for forming the first insulating layer 111 and the first conductor layer 121, a desired number of insulating layers 11 and conductor layers 12 are laminated on the second conductor layer 122 and the second insulating layer 112. The uppermost conductor layer 12 is formed to have patterns including the conductor pads (12fp).

Next, as illustrated in FIG. 5K, the solder resist layer (Lf) is formed by forming a photosensitive epoxy resin or polyimide resin layer on the surfaces of the insulating layer 11 and the conductor layer 12, and the openings (Lfa) that define the conductor pads (12fp) are formed using a photolithography technology.

Next, as illustrated in FIG. 5L, the support substrate (SP) is removed. The lower surface of the second metal film layer (ML2) under the conductor pads (12bp) is exposed. In removing the support substrate (SP), for example, the adhesive layer (AL) is irradiated with laser light and is softened, and then, the second metal film layer (ML2) of the support substrate (SP) is peeled off.

Next, the second metal film layer (ML2) is removed by etching, and the lower surfaces of the conductor pads (12bp) and the lower surface of the first insulating layer 111 are exposed. On the lower surfaces of the conductor pads (12bp) and on the lower surface of the first insulating layer 111, the solder resist layer (Lb) is formed by forming a photosensitive epoxy resin or polyimide resin layer on the surfaces of the insulating layer 11 and conductor layer 12. In the solder resist layer (Lb), the openings (Lba) that define the conductor pads (12bp) are formed using a photolithography technology. As illustrated in FIG. 5M, the manufacture of the wiring substrate 1 is completed.

Japanese Patent Application Laid-Open Publication No. 2000-252622 describes a wiring substrate in which a conductor circuit is formed on a resin insulating layer. A surface of the conductor circuit is roughened with a chemical solution, and a resin insulating layer is further formed on the conductor circuit. The entire contents of this publication are incorporated herein by reference.

It is thought that in Japanese Patent Application Laid-Open Publication No. 2000-252622, desirable adhesion of the further resin insulating layer laminated on the conductor circuit to the side surfaces of the conductor circuit and the resin insulating layer below the conductor circuit may not be obtained.

A wiring substrate according to an embodiment of the present invention includes: a first insulating layer; a first conductive layer that is formed on the first insulating layer; and a second insulating layer that is formed on the first insulating layer and the first conductive layer. The first conductive layer includes wirings having a minimum wiring width of 3 μm or less and a minimum inter-wiring distance of 3 μm or less, and vertically striping concave and convex portions extending along a thickness direction of the first conductor layer is formed on side surfaces of the first conductor layer.

A method for manufacturing a wiring substrate according to an embodiment of the present invention includes: forming a first conductor layer on a first insulating layer; and forming a second insulating layer on the first conductor layer and the first insulating layer. The forming of the first conductor layer includes: forming a metal film layer on the first insulating layer; forming a plating film layer on the metal film layer; and removing, by ion beam etching, the metal film layer that is exposed from patterns of the plating film layer, and the removing of the metal film layer by ion beam etching includes forming, on side surfaces of the first conductor layer, vertically striping concave and convex portions extending along a thickness direction of the first conductor layer.

According to an embodiment of the present invention, a wiring substrate achieves good adhesion between the second insulating layer and the side surfaces of the first conductor layer and the upper surface of the first insulating layer.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
a first insulating layer;
a conductive layer formed on the first insulating layer and comprising a plurality of wirings; and
a second insulating layer formed on the first insulating layer such that the second insulating layer is covering the conductive layer,
wherein the conductive layer is formed such that the plurality of wirings has a minimum wiring width of 3 μm or less and a minimum inter-wiring distance of 3 μm or less and has side surfaces having concave and convex portions forming vertical stripes extending along a thickness direction of the conductor layer.

2. The wiring substrate according to claim 1, wherein the conductor layer includes a metal film layer in contact with the first insulating layer and a plating film layer formed on the metal film layer such that the concave and convex portions are formed to extend across the plating film layer and the metal film layer.

3. The wiring substrate according to claim 1, wherein the conductive layer is formed such that the concave and convex portions have recesses extending in the thickness direction of the conductor layer and protrusions corresponding to boundaries between adjacent recesses and that a maximum distance between adjacent boundaries in a direction orthogonal to the thickness direction of the conductor layer on the side surfaces is in a range of 0.2 μm to 1.0 μm.

4. The wiring substrate according to claim 1, wherein the conductor layer has a thickness in a range of 1 μm to 5 μm.

5. The wiring substrate according to claim 2, wherein the conductive layer is formed such that the metal film layer is a sputtered film formed by sputtering.

6. The wiring substrate according to claim 2, wherein the conductive layer is formed such that the metal film layer has a thickness in a range of 0.02 μm to 0.5 μm.

7. The wiring substrate according to claim 2, wherein the conductive layer is formed such that the metal film layer includes a plurality of sputtered films comprising mutually different metal materials.

8. The wiring substrate according to claim 2, wherein the conductive layer is formed such that the concave and convex portions have recesses extending in the thickness direction of the conductor layer and protrusions corresponding to boundaries between adjacent recesses and that a maximum distance between adjacent boundaries in a direction orthogonal to the thickness direction of the conductor layer on the side surfaces is in a range of 0.2 μm to 1.0 μm.

9. The wiring substrate according to claim 2, wherein the conductor layer has a thickness in a range of 1 μm to 5 μm.

10. The wiring substrate according to claim 8, wherein the conductive layer is formed such that the metal film layer is a sputtered film formed by sputtering.

11. The wiring substrate according to claim 8, wherein the conductive layer is formed such that the metal film layer has a thickness in a range of 0.02 μm to 0.5 μm.

12. The wiring substrate according to claim 8, wherein the conductive layer is formed such that the metal film layer includes a plurality of sputtered films comprising mutually different metal materials.

13. The wiring substrate according to claim 3, wherein the conductor layer has a thickness in a range of 1 μm to 5 μm.

14. The wiring substrate according to claim 9, wherein the conductive layer is formed such that the metal film layer is a sputtered film formed by sputtering.

15. The wiring substrate according to claim 9, wherein the conductive layer is formed such that the metal film layer has a thickness in a range of 0.02 μm to 0.5 μm.

16. The wiring substrate according to claim 9, wherein the conductive layer is formed such that the metal film layer includes a plurality of sputtered films comprising mutually different metal materials.

17. A method for manufacturing a wiring substrate, comprising:
forming a conductor layer on a first insulating layer; and
forming a second insulating layer on the first insulating layer such that the second insulating layer covers the conductor layer,
wherein the forming the conductor layer includes forming a metal film layer on the first insulating layer, forming a plating film layer having patterns on the metal film layer, and applying ion beam etching on the metal film and plating film layers such that portions of the metal film layer exposed from the patterns of the plating film layer are removed and that concave and convex portions forming vertical stripes and extending along a thickness direction of the conductor layer are formed on side surfaces of the conductor layer.

18. The method for manufacturing a wiring substrate according to claim 17, wherein the applying the ion beam etching on the metal film and plating film layers includes forming the concave and convex portions on side surfaces of the plating film layer and side surfaces of the metal film layer.

19. The method for manufacturing a wiring substrate according to claim 17, wherein the applying the ion beam etching on the metal film and plating film layers includes forming recesses extending in a thickness direction of the plating film layer such that a maximum distance between adjacent boundaries of the recesses in a direction orthogonal to the thickness direction of the plating film layer on side surfaces of the patterns of the plating film layer is in a range of 0.2 μm to 1.0 μm.

20. The method for manufacturing a wiring substrate according to claim 17, wherein the metal film layer is formed by sputtering.
